(19) United States
(12) Patent Application Publication
(10) Pub. No.: US 2023/0413638 A1
(43) Pub. Date: Dec. 21, 2023

(54) DISPLAY PANEL, MANUFACTURING METHOD THEREOF, AND DISPLAY APPARATUS

(71) Applicants: YUNNAN INVENSIGHT OPTOELECTRONICS TECHNOLOGY CO., LTD., Kunming (CN); BOE TECHNOLOGY GROUP CO., LTD., Beijing (CN)

(72) Inventors: Zongshun YANG, Beijing (CN); Dacheng ZHANG, Beijing (CN); Kuanta HUANG, Beijing (CN); Xiaochuan CHEN, Beijing (CN)

(21) Appl. No.: 18/253,222

(22) PCT Filed: Nov. 5, 2021
(86) PCT No.: PCT/CN2021/128964

§ 371 Date: May 17, 2023

(51) Int. Cl. H10K 59/38; H10K 59/122; H01L 33/50

(52) U.S. Cl. CPC H10K 59/38; H10K 59/122; H01L 33/50

(57) ABSTRACT

The embodiments of the present disclosure provides a display panel and a display apparatus, a first color filter and a second color filter that are adjacent and have different light transmission colors, light transmittance of the second color filter is smaller than light transmittance of the first color filter; the first peripheral portion of the first color filter surrounds the first light-transmitting portion and includes a first portion close to the second color filter; the second peripheral portion of the second color filter surrounds the second light-transmitting portion and includes a first portion close to the first color filter; the first portion of the second peripheral portion includes a first sub-layer and a second sub-layer that overlap in the longitudinal direction and spaced apart from each other, and the first portion of the first peripheral portion is between the first sub-layer and the second sub-layer in the longitudinal direction.

### TECHNICAL FIELD

The embodiments of the present disclosure relate to a display panel, a manufacturing method thereof, and a display apparatus.

### BACKGROUND

In a display apparatus, color crosstalk is prone to occur between adjacent color sub-pixels, especially in a display apparatus with high pixel density (Pixel Per Inch, PPI for short). For example, in a micro-display apparatus with high PPI, a size of a sub-pixel is very small, and a spacing between adjacent sub-pixels is also very small, for example, from 3 μm to 8 μm, in this case, color crosstalk is more likely to occur. Usually a shading black matrix is used to define a plurality of sub-pixels, so that the light-shielding black matrix is used to block crosstalk light between the sub-pixels, so as to prevent the phenomenon of color crosstalk.

### SUMMARY

At least one embodiment of the present disclosure provides a display panel, the display panel comprises a substrate and a plurality of sub-pixels. The substrate includes a main surface; the plurality of sub-pixels are arranged on the main surface of the substrate in an array, each of the plurality of sub-pixels includes a light-emitting device and a color filter on a light-emitting side of the light-emitting device; the color filter of the plurality of sub-pixels includes a first color filter and a second color filter that are adjacent, light transmission color of the first color filter and light transmission color of the second color filter are different from each other, light transmittance of the second color filter is smaller than light transmittance of the first color filter; the first color filter includes a first light-transmitting portion and a first peripheral portion, the first light-transmitting portion is configured to allow light of the sub-pixels where the first light-transmitting portion is located to pass through to emit from the display panel; the first peripheral portion at least partially surrounds the first light-transmitting portion, and the first peripheral portion includes a first portion located on a side of the first light-transmitting portion close to the second color filter; the second color filter includes a second light-transmitting portion and a second peripheral portion, the second light-transmitting portion is configured to allow light of the sub-pixels where the second light-transmitting portion is located to pass through to emit from the display panel; the second peripheral portion at least partially surrounds the second light-transmitting portion, and the second peripheral portion includes a first portion located on a side of the second light-transmitting portion close to the first color filter; the first portion of the second peripheral portion includes a plurality of sub-layers that are at least partially overlapped and spaced apart from each other in a longitudinal direction perpendicular to the main surface of the substrate, the plurality of sub-layers include a first sub-layer and a second sub-layer, and at least a part of the first portion of the first peripheral portion is located between the first sub-layer and the second sub-layer in the longitudinal direction.

For example, in the display panel provided by at least one embodiment of the present disclosure, the second color filter is a blue color filter that allows blue light to pass through.

For example, in the display panel provided by at least one embodiment of the present disclosure, the first sub-layer is on a side of the second sub-layer close to the substrate; an orthographic projection of the first sub-layer on the main surface of the substrate is within an orthographic projection of the second sub-layer on the main surface of the substrate, and an area of the orthographic projection of the first sub-layer on the main surface of the substrate is smaller than an area of the orthographic projection of the second sub-layer on the main surface of the substrate.

For example, in the display panel provided by at least one embodiment of the present disclosure, a direction in which the first color filter and the second color filter are arranged is a lateral direction; and a width of the first sub-layer in the lateral direction is smaller than a width of the second sub-layer in the lateral direction.

For example, in the display panel provided by at least one embodiment of the present disclosure, the first portion of the first peripheral portion comprises an inner portion and an outer portion, the inner portion is sandwiched between the first sub-layer and the second sub-layer, wherein the inner portion is overlapped with both the first sub-layer and the second sub-layer in the longitudinal direction; the outer portion is integral with the inner portion and on a side of the inner portion close to the first light-transmitting portion in the lateral direction, wherein the outer portion is not overlapped with the first sub-layer, and is overlapped with the second sub-layer in the longitudinal direction.

For example, in the display panel provided by at least one embodiment of the present disclosure, the outer portion covers a side surface of the first sub-layer and is in contact with the side surface of the first sub-layer, and the side surface of the first sub-layer is intersected with the lateral direction.

For example, in the display panel provided by at least one embodiment of the present disclosure, the first sub-layer is on a side of the second sub-layer close to the substrate; and a thickness of the first sub-layer in the longitudinal direction is greater than a thickness of the second sub-layer in the longitudinal direction.

For example, in the display panel provided by at least one embodiment of the present disclosure, the first portion of the first peripheral portion comprises a plurality of sub-layers that are at least partially overlapped in the longitudinal direction and are spaced apart from each other in the longitudinal direction; and the plurality of sub-layers of the first portion of the first peripheral portion and the plurality of sub-layers of the first portion of the second peripheral portion are alternately stacked in the longitudinal direction.

For example, in the display panel provided by at least one embodiment of the present disclosure, among the plurality of sub-layers of the first portion of the first peripheral portion and the plurality of sub-layers of the first portion of the second peripheral portion, the first sub-layer is closest to the substrate.

For example, the display panel provided by at least one embodiment of the present disclosure further comprises a flat layer, the flat layer covers the main surface of the substrate, and has a flat surface away from the substrate, the first color filter and the second color filter are located on the flat surface, and the first sub-layer is in contact with the flat surface.

For example, in the display panel provided by at least one embodiment of the present disclosure, among the plurality of sub-layers of the first portion of the first peripheral portion and the plurality of sub-layers of the first portion of the second peripheral portion, the second sub-layer is farthest away from the substrate.

For example, in the display panel provided by at least one embodiment of the present disclosure, the plurality of sub-layers of the first portion of the second peripheral portion are arranged in the longitudinal direction, and in a direction from close to the substrate to away from the substrate, thicknesses of the plurality of sub-layers in the longitudinal direction of the first portion of the second peripheral portion gradually decrease.

For example, in the display panel provided by at least one embodiment of the present disclosure, a direction in which the first color filter and the second color filter are arranged is a lateral direction; the plurality of sub-layers of the first portion of the second peripheral portion are arranged in the longitudinal direction, in a direction from close to the substrate to away from the substrate, widths of the plurality of sub-layers of the first portion of the second peripheral portion in the lateral direction gradually increase.

For example, in the display panel provided by at least one embodiment of the present disclosure, the color filter of the plurality of sub-pixels further comprises a third color filter adjacent to the second color filter and on a side of the second color filter away from the first color filter, light transmission colors of the first color filter, the second color filter and the third color filter are different from each other, the light transmittance of the second color filter is smaller than a light transmittance of the third color filter; the third color filter comprises a third light-transmitting portion and a third peripheral portion, the third light-transmitting portion is configured to allow light of the sub-pixel where the third light-transmitting portion is located to pass through to emit from the display panel; the third peripheral portion at least partially surrounds the third light-transmitting portion, and the third peripheral portion comprises a first portion on a side of the third light-transmitting portion close to the second color filter; the second peripheral portion further comprises a second portion on a side of the second light-transmitting portion close to the third color filter; the second portion of the second peripheral portion comprises a plurality of sub-layers that are at least partially overlapped in the longitudinal direction perpendicular to the main surface of the substrate and are spaced apart from each other in the longitudinal direction, the plurality of sub-layers of the second portion of the second peripheral portion comprises a third sub-layer and a fourth sub-layer, and at least a part of the first portion of the third peripheral portion is between the third sub-layer and the fourth sub-layer in the longitudinal direction.

For example, in the display panel provided by at least one embodiment of the present disclosure, the first color filter is a green color filter that allows green light to pass through, and the third color filter is a red color filter that allows red light to pass through.

For example, in the display panel provided by at least one embodiment of the present disclosure, the second color filter is substantially axisymmetric with respect to a symmetry axis along the longitudinal direction, and the first peripheral portion and the third peripheral portion are substantially axisymmetric with respect to the symmetry axis.

For example, in the display panel provided by at least one embodiment of the present disclosure, a cross section of the second color filter in the longitudinal direction is in a shape of a Chinese word “ [symbol] ”.

For example, in the display panel provided by at least one embodiment of the present disclosure, one of the first color filter, one of the second color filter, and one of the third color filter which are sequentially arranged in sequence constitute a repeating unit, and a plurality of the repeating units are repeatedly arranged to provide one of the color filter for each of the plurality of sub-pixels.

For example, in the display panel provided by at least one embodiment of the present disclosure, in one of the repeating units, the first peripheral portion further comprises a second portion on a side of the first light-transmitting portion away from the second color filter, and the third peripheral portion further comprises a second portion on a side of the third light-transmitting portion close to the first color filter; and the second portion of the first peripheral portion comprises a plurality of sub-layers that are at least partially overlapped in the longitudinal direction perpendicular to the main surface of the substrate and are spaced apart from each other in the longitudinal direction, the plurality of sub-layers of the first peripheral portion comprise a fifth sub-layer and a sixth sub-layer, and at least a part of a second portion of the third peripheral portion of the third color filter in the repeating unit adjacent to the one of the repeating units is located between the fifth sub-layer and the sixth sub-layer in the longitudinal direction.

For example, in the display panel provided by at least one embodiment of the present disclosure, in one of the repeating units, a shape and a size of the second portion of the first peripheral portion are same as a shape and a size of the first portion of the second peripheral portion, respectively; and a shape and a size of the second portion of the third peripheral portion are respectively same as a shape and a size of the first portion of the first peripheral portion.

For example, in the display panel provided by at least one embodiment of the present disclosure, a cross section of the third color filter in the longitudinal direction is in a shape of a Chinese word “ [symbol] ”, and a protrusion of the shape of the Chinese word “ [symbol] ” protrudes toward the substrate.

For example, the display panel provided by at least one embodiment of the present disclosure further comprises a pixel definition layer, the pixel definition layer defines openings of the plurality of the sub-pixels of the pixel array, wherein the light-emitting device are at least partially located in the openings; an orthographic projection of the first light-transmitting portion, an orthographic projection of the second light-transmitting portion, and an orthographic projection of the third light-transmitting portion on the main surface of the substrate are respectively located in orthographic projections of the openings of the sub-pixels corresponding to the first color filter, the second color filter, and the third color filter on the main surface of the substrate respectively, and an orthographic projection of the first peripheral portion, an orthographic projection of the second peripheral portion, and an orthographic projection of the third peripheral portion on the main surface of the substrate are all within an orthographic projection of the pixel definition layer on the main surface of the substrate.

At least one embodiment of the present disclosure provides a display apparatus, the display apparatus comprises any one of the display panel provided by the embodiments of the present disclosure.

### BRIEF DESCRIPTION OF THE DRAWINGS

In order to clearly illustrate the technical solution of the embodiments of the present disclosure, the drawings of the embodiments will be briefly described. It is apparent that the described drawings are only related to some embodiments of the present disclosure and thus are not limitative of the present disclosure.

FIG. 1 is a planar schematic diagram of a display panel provided by at least one embodiment of the present disclosure;

FIG. 2A is a cross-sectional schematic diagram taken along a line A-A′ in FIG. 1;

FIG. 2B is a partial schematic diagram of a color filter layer in FIG. 2A;

FIG. 2C is an enlarged schematic diagram of a part L in FIG. 2B;

FIG. 2D is a partial enlarged diagram of another display panel provided by an embodiment at a same position L as in FIG. 2B;

FIG. 3 is a schematic diagram of still another display panel provided by at least one embodiment of the present disclosure;

FIG. 4 is a schematic diagram of a display apparatus provided by at least one embodiment of the present disclosure; and

FIG. 5A to FIG. 5D are schematic diagrams of a method for manufacturing a display panel provided by at least one embodiment of the present disclosure.

### DETAILED DESCRIPTION

In order to make objects, technical details and advantages of embodiments of the present disclosure clear, the technical solutions of the embodiments will be described in a clearly and fully understandable way in connection with the related drawings. It is apparent that the described embodiments are just a part but not all of the embodiments of the present disclosure. Based on the described embodiments herein, those skilled in the art can obtain, without any inventive work, other embodiment(s) which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the description and claims of the present disclosure, are not intended to indicate any sequence, amount or importance, but distinguish various components. The terms “comprises,” “comprising,” “includes,” “including,” etc., are intended to specify that the elements or the objects stated before these terms encompass the elements or the objects listed after these terms as well as equivalents thereof, but do not exclude other elements or objects. The phrases “connect”, “connected”, etc., are not intended to define a physical connection or a mechanical connection, but may comprise an electrical connection which is direct or indirect. The terms “on,” “under,” “left,” “right” and the like are only used to indicate relative position relationship, and in a case that the position of an object is described as being changed, the relative position relationship may be changed accordingly.

At least one embodiment of the present disclosure provides a display panel, and the display panel includes a substrate and a plurality of sub-pixels. The substrate includes a main surface; the plurality of sub-pixels are arranged on the main surface of the substrate in an array, each of the plurality of sub-pixels includes a light-emitting device and a color filter on a light-emitting side of the light-emitting device; the color filter of the plurality of sub-pixels includes a first color filter and a second color filter that are adjacent, light transmission color of the first color filter and light transmission color of the second color filter are different from each other, light transmittance of the second color filter is smaller than light transmittance of the first color filter; the first color filter includes a first light-transmitting portion and a first peripheral portion, the first light-transmitting portion is configured to allow light of the sub-pixels where the first light-transmitting portion is located to pass through to emit from the display panel; the first peripheral portion at least partially surrounds the first light-transmitting portion, and the first peripheral portion includes a first portion located on a side of the first light-transmitting portion close to the second color filter; the second color filter includes a second light-transmitting portion and a second peripheral portion, the second light-transmitting portion is configured to allow light of the sub-pixels where the second light-transmitting portion is located to pass through to emit from the display panel; the second peripheral portion at least partially surrounds the second light-transmitting portion, and the second peripheral portion includes a first portion located on a side of the second light-transmitting portion close to the first color filter; the first portion of the second peripheral portion includes a plurality of sub-layers that are at least partially overlapped and spaced apart from each other in a longitudinal direction perpendicular to the main surface of the substrate, the plurality of sub-layers include a first sub-layer and a second sub-layer, and at least a part of the first portion of the first peripheral portion is located between the first sub-layer and the second sub-layer in the longitudinal direction. The light emitted by the light-emitting layer passes through the color filter of each of the sub-pixels and emits colored light corresponding to the color filter, overlapping positions of the color filters of different colors do not emit light, so that color display is realized.

At least one embodiment of the present disclosure further provides a display apparatus, and the display apparatus includes any one of the display panels provided by the embodiments of the present disclosure.

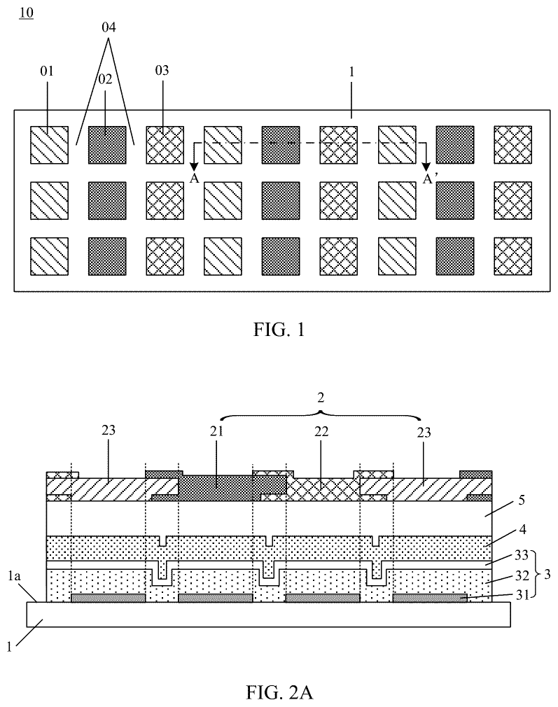

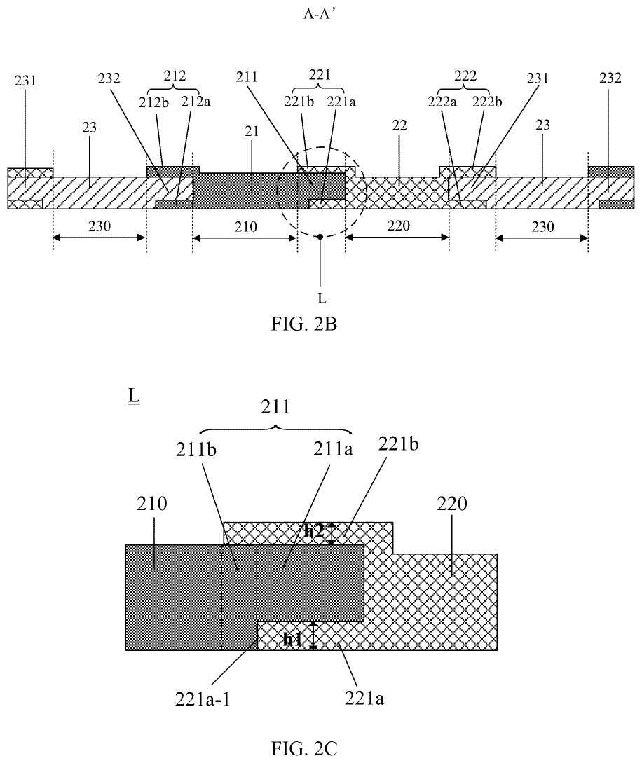

Exemplarily, FIG. 1 is a planar schematic diagram of a display panel provided by at least one embodiment of the present disclosure, and FIG. 2A is a cross-sectional schematic diagram taken along a line A-A′ in FIG. 1. As shown in FIG. 1, the display panel 10 provided by at least one embodiment of the present disclosure includes a substrate 1 and a plurality of sub-pixels 01/02/03. The substrate 1 includes a main surface 1a; the plurality of sub-pixels 01/02/03 are arranged on the main surface 1a of the substrate 1 in an array, each of the plurality of sub-pixels 01/02/03 includes a light-emitting device 3 and a color filter 21/22/23 located on a light-emitting side of the light-emitting device 3. Regions represented by the numerals 01, 02, and 03 in FIG. 1 represent light-emitting regions of the plurality of sub-pixels; and the display panel 10 further includes non light-emitting regions 04 located among the light-emitting regions of adjacent sub-pixels. For example, as shown in FIG. 2A, the light-emitting device 3 includes an anode 31, a light-emitting layer 32 and a cathode 33, the light-emitting layer 32 is located between the anode 31 and the cathode 33, for example, the cathode 33 is a continuous integral electrode covering the plurality of sub-pixels. For example, light emitted by the light-emitting layer 32 is white light, the light emitted by the light-emitting layer 32 passes through the color filter of each of the plurality of sub-pixels to emit color light corresponding to the color filter, overlapping positions of the color filters of different colors do not emit light, so that the color display is realized. In the display panel provided by the embodiment of the present disclosure, the light emitted by the light-emitting layer passes through two color filters with low transmittance in the overlapping positions, so that it is beneficial to reduce light transmittance of the non light-emitting regions, and a better light blocking effect is obtained in the non light-emitting regions, in addition, crosstalk light is better blocked in the non light-emitting regions, thereby the crosstalk phenomenon between adjacent sub-pixels is better prevented. In the embodiments of the present disclosure, the non light-emitting regions located between the light-emitting regions of adjacent sub-pixels are non-display regions.

For example, the light-emitting device 3 is an organic light-emitting diode (OLED) or an inorganic light-emitting diode. However, the light-emitting device 3 is not limited to the kind listed here.

For example, in the embodiment shown in FIG. 1A, the substrate 1 is a silicon-based substrate. The manufacturing process of the silicon-based substrate is mature, and the performance of the silicon-based substrate is stable, which is suitable for manufacturing highly integrated micro display apparatus. For example, the display apparatus is a silicon-based micro organic light-emitting diode display apparatus.

As shown in FIG. 2A to FIG. 2B, the color filter of the plurality of sub-pixels includes a first color filter 21 and a second color filter 22 that are adjacent, light transmittance color of the first color filter 21 and light transmittance color of the second color filter 22 are different from each other, and light transmittance of the second color filter 22 is smaller than light transmittance of the first color filter 21.

Because the light transmittance color of the first color filter 21 and the light transmittance color of the second color filter 22 are different from each other, colors of the light that the first color filter 21 and the second color filter 22 respectively allow to pass through are different. Therefore, a position where the first color filter 21 and the second color filter 22 are overlapped with each other in the longitudinal direction perpendicular to the main surface 1a of the substrate 1 is opaque. Similarly, in the display panel 10, colors of the color filters of adjacent sub-pixels are different, positions where the color filters of the adjacent sub-pixels are overlapped with each other in the longitudinal direction are all opaque.

Referring to FIG. 2A to FIG. 2B, the first color filter 21 includes a first light-transmitting portion 210 and a first peripheral portion, the first light-transmitting portion 210 is configured to allow the light of the sub-pixel where the first light-transmitting portion 210 is located to pass through the first light-transmitting portion 210 to emit from the display panel the first peripheral portion at least partially surrounds the first transparent portion 210, and includes a first portion 211 located on a side of the first light-transmitting portion 210 close to the second color filter 22, the region where the first peripheral portion is located is a non light-emitting region (non-display region); the second color filter 22 includes a second light-transmitting portion 220 and a second peripheral portion, the second light-transmitting portion 220 is configured to allow light of the sub-pixel where the second light-transmitting portion 220 is located to pass through the second light-transmitting portion 220 to emit from the display panel 10; the second peripheral portion at least partially surrounds the second light-transmitting portion 220, and includes a first portion 221 located on a side of the second light-transmitting portion 220 close to the first color filter 21, the region where the second peripheral portion is located is a non light-emitting region (non-display region); the first portion 221 of the second peripheral portion includes a plurality of sub-layers that are at least partially overlapped in the longitudinal direction perpendicular to the main surface 1a of the substrate 1 and are spaced apart from each other in the longitudinal direction. For example, in the present embodiment, the plurality of sub-layers include a first sub-layer 221a and a second sub-layer 221b, the first sub-layer 221a and the second sub-layer 221b are at least partially overlapped in the longitudinal direction and are spaced apart from each other in the longitudinal direction; in the longitudinal direction, at least a part of the first portion 211 of the first peripheral portion is located between the first sub-layer 221a and the second sub-layer 221b, for example, at least a part of the first portion 211 of the first peripheral portion is sandwiched between the first sub-layer 221a and the second sub-layer 221b. For example, the first light-transmitting portion 210 is integral with the first peripheral portion. For example, the second light-transmitting portion 220 is integral with the second peripheral portion. Because the light transmittance of the second color filter 22 is smaller than the light transmittance of the first color filter 21, therefore, a plurality of sub-layers of the second color filter 22, i.e. the first sub-layer 221a and the second sub-layer 221b, are arranged at the position where the second color filter 22 and the first color filter 21 are overlapped, in the case that the light from the light-emitting layer 32 reaches the overlapping region (that is, the non light-emitting region) where the second color filter 22 and the first color filter 21 are overlapped, the light emitted by the light-emitting layer sequentially passes through the first sub-layer 221a, the first portion 211 of the first peripheral portion and the second sub-layer 221b, therefore, the light emitted by the light-emitting layer will pass through two color filters with lower light transmittance, so that it is beneficial to reduce the light transmittance of the non light-emitting region, and a better light-blocking effect in the non light-emitting region is obtained, and the crosstalk light is better blocked in the non light-emitting region, and thereby better prevention of crosstalk between the adjacent sub-pixels is achieved.

For example, the second color filter 22 is a blue color filter that allows blue light to pass through. Because a filter of blue color has a lower light transmittance compared with filters of other colors, experiments have shown that the light blocking effect in the non light-emitting region is better by using the filter of blue color as the second color filter 22. For example, in the embodiment shown in FIG. 2A, the first color filter 21 is a green color filter that allows green light to pass through. Of course, in other embodiments, the colors of the first color filter 21 and the second color filter 22 may also be other colors, as long as the light transmittance of the second color filter 22 is smaller than the light transmittance of the first color filter 21.

For example, the first sub-layer 221a is located on a side of the second sub-layer 221b close to the substrate 1; an orthographic projection of the first sub-layer 221a on the main surface 1a of the substrate 1 is located within an orthographic projection of the second sub-layer 221b on the main surface 1a of the substrate 1, and an area of the orthographic projection of the first sub-layer 221a on the main surface 1a of the substrate 1 is smaller than an area of the orthographic projection of the second sub-layer 221 b on the main surface 1a of the substrate 1. Therefore, the second sub-layer 221b farther away from the light-emitting device 3 further achieves a better effect of absorbing crosstalk light from adjacent pixels, and experiments have proved that this scheme is beneficial to achieve a better anti-crosstalk effect.

For example, in other embodiments, the number of the sub-layers of the second color filter 22 may be more than two, and in the embodiment shown in FIG. 2A, the case that the number of the sub-layers of the second color filter 22 is two is taken as an example.

For example, the direction in which the first color filter 21 and the second color filter 22 are arranged is a lateral direction; a width of the first sub-layer 221a in the lateral direction is smaller than a width of the second sub-layer 221b in the lateral direction, so that at an edge of the entire second color filter 22, a region between an edge of the first sub-layer 221a and an edge of the second sub-layer 221b has a better anti-crosstalk effect in the lateral direction.

FIG. 2C is an enlarged schematic diagram of a part L in FIG. 2B. As shown in FIG. 2C, for example, the first portion 211 of the first peripheral portion includes an inner portion 211a and an outer portion 211b. The inner portion 211a is sandwiched between the first sub-layer 221a and the second sub-layer 221b, and is overlapped with both the first sub-layer 221a and the second sub-layer 221b in the longitudinal direction; the outer portion 211b and the inner portion 211a constitute an integral structure, and the outer portion 211b is located on a side of the inner portion 211a close to the first light-transmitting portion 210 in the lateral direction, the outer portion 211b is not overlapped with the first sub-layer 221a, and is overlapped with the second sub-layer 221b in the longitudinal direction, therefore, at the edge of the entire second color filter 22, the region between the edge of the first sub-layer 221a and the edge of the second sub-layer 221b, that is, the position where the outer portion 211b is located, has a better anti-crosstalk effect in the lateral direction. For example, the outer portion 211b covers a side surface 221a-1 of the first sub-layer 221a and is in contact with the side surface 221a-1 of the first sub-layer 221a, the side surface 221a-1 of the first sub-layer 221a is intersected with the lateral direction, so that the structure is compact, which facilitates the realization of high PPI, and it is beneficial to enabling the bottom surface of the first color filter 21 close to the substrate 1 to be flush with the bottom surface of the second color filter 22 close to the substrate 1, and it is beneficial to improving the display uniformity of the entire display panel.

For example, the thickness h1 of the first sub-layer 221a of the second color filter 22 in the longitudinal direction is greater than the thickness h2 of the second sub-layer 221b of the second color filter 22 in the longitudinal direction. Experiments have proved that, the first sub-layer 221a with a larger thickness can achieve a better light blocking effect and prevent the problem of light crosstalk between the adjacent sub-pixels.

For example, FIG. 2D is a partial enlarged diagram of the display panel provided by another embodiment at the same position L as in FIG. 2B. As shown in FIG. 2D, in the display panel provided by at least another embodiment, the first portion 211 of the first peripheral portion of the first color filter 21 also includes a plurality of sub-layers that are at least partially overlapped in the longitudinal direction and are spaced apart from each other in the longitudinal direction; the plurality of sub-layers of the first portion of the first peripheral portion and the plurality of sub-layers of the first portion of the second peripheral portion are alternately stacked in the longitudinal direction. For example, the inner portion 211a of the first portion 211 of the first color filter 21 includes a plurality of sub-layers that are at least partially overlapped in the longitudinal direction and spaced apart from each other in the longitudinal direction, For example, the inner portion 211a of the first portion 211 includes a first sub-layer 213 and a second sub-layer 214, the first sub-layer 213 and the second sub-layer 214 of the first color filter 21 and the first sub-layer 221a and the second sub-layer 221b of the second color filter 22 are alternately stacked in the longitudinal direction. In the present embodiment, the second color filter 22 with lower light transmittance and the first color filter 21 with lower light transmittance both include a plurality of sub-layers, and a better light blocking effect can be achieved, and the problem of light crosstalk between the adjacent sub-pixels can be prevented.

For example, in the embodiment shown in FIG. 2D, the first portion 221 of the second peripheral portion of the second color filter 22 further includes a third sub-layer 221c. For example, the thickness h1 of the first sub-layer 221a of the second color filter 22 in the longitudinal direction and the thickness h3 of the third sub-layer 221c of the second color filter 22 in the longitudinal direction are both greater than the thickness h2 of the second sub-layer 221b of the second color filter 22 in the longitudinal direction. Or, in other embodiments, the plurality of sub-layers of the first portion 221 of the second peripheral portion of the second color filter 22 are arranged in the longitudinal direction, the thicknesses of the plurality of sub-layers in the longitudinal direction of the first portion 221 of the second peripheral portion gradually decrease in the direction from close to the substrate 1 to away from the substrate 1; that is, for example, in the embodiment shown in FIG. 2D, the thickness h1 of the first sub-layer 221a in the longitudinal direction, the thickness h3 of the third sub-layer 221c in the longitudinal direction, and the thickness h2 of the second sub-layer 221b in the longitudinal direction gradually decrease.

For example, as shown in FIG. 2D, among the plurality of sub-layers of the first portion 211 of the first peripheral portion of the first color filter 21 and the plurality of sub-layers of the first portion 221 of the second peripheral portion of the second color filter 22, the first sub-layer 221a is closest to the substrate 1, so that light from the light-emitting layer 32 first passes through the second color filter with the lower light transmittance in the non light-emitting region 04, then passes through the first color filter with the higher light transmittance, thereby a better light blocking effect can be achieved in the non light-emitting region 04, and the problem of light crosstalk between the adjacent sub-pixels can be better prevented.

Other features and corresponding technical effects of the display panel shown in FIG. 2D are the same as those of the embodiment shown in FIG. 2A to FIG. 2C, which can be referred to the descriptions in the embodiments shown in FIG. 2A to FIG. 2C.

For example, as shown in FIG. 2A, the display panel 10 further includes a thin film encapsulation layer 4, and the thin film encapsulation layer 4 covers the light-emitting devices of the plurality of sub-pixels in the entire display region. The display panel 10 further includes a flat layer 5, the flat layer 5 covers the main surface 1a of the substrate 1, for example, the flat layer 5 is located on a side of the thin film encapsulation layer 4 away from the substrate 1 and covers the thin film encapsulation layer 4, and the flat layer 5 has a flat surface away from the substrate 1, the first color filter 21 and the second color filter 22 are located on the flat surface, and the first sub-layer 221a of the second color filter 22 is in contact with the flat surface. For example, the bottom surface of the first color filter 21 close to the substrate 1 is flush with the bottom surface of the second color filter 22 close to the substrate 1, the bottom surfaces are both in contact with the flat surface, and it is beneficial to the display uniformity of the entire display panel.

For example, as shown in FIG. 2B or FIG. 2D, among the plurality of sub-layers of the first portion 211 of the first peripheral portion of the first color filter 21 and the plurality of sub-layers of the first portion 221 of the second peripheral portion of the first color filter 21, the second sub-layer 221b of the first portion 221 of the second peripheral portion of the second color filter 22 is farthest away from the substrate 1. In this way, it can be ensured that the path of the light from the light-emitting layer 32 in the non light-emitting region 04 finally passes through the second color filter 22 with the lower light transmittance, so that a better light blocking effect in the non light-emitting region 04 can be achieved, and the problem of light crosstalk between the adjacent sub-pixels can be better prevented.

For example, as shown in FIG. 2A to FIG. 2B, the color filter of the plurality of sub-pixels further includes a third color filter 23 which is adjacent to the second color filter 22 and located on a side of the second color filter 22 away from the first color filter 21, the light transmission colors of the first color filter 21, the second color filter 22 and the third color filter 23 are different from each other, and the light transmittance of the second color filter 22 is smaller than the light transmittance of the third color filter 23, that is, the light transmittance of the second color filter 22 is smaller than the light transmittance of the first color filter 21 and smaller than the light transmittance of the third color filter 23. The third color filter 23 includes a third light-transmitting portion 230 and a third peripheral portion. The third light-transmitting portion 230 is configured to allow the light of the sub-pixel where the third light-transmitting portion 230 is located to pass through to emit from the display panel 10; the third peripheral portion at least partially surrounds the third light-transmitting portion 230, and the third peripheral portion includes a first portion 231 located on a side of the third light-transmitting portion 230 close to the second color filter 22, a region where the third peripheral portion is located is a non light-emitting region (non-display region); the second peripheral portion further includes a second portion 232 located on a side of the second light-transmitting portion 220 close to the third color filter 23. The second portion 222 of the second peripheral portion includes a plurality of sub-layers that are at least partially overlapped in the longitudinal direction perpendicular to the main surface 1a of the substrate 1 and spaced apart from each other in the longitudinal direction, the plurality of sub-layers of the second portion 222 of the second peripheral portion include a third sub-layer 222a and a fourth sub-layer 222b, at least a part of the first portion 231 of the third peripheral portion is located between the third sub-layer 222a and the fourth sub-layer 222b in the longitudinal direction, similar to the relationship between the first portion 221 of the second peripheral portion and the first portion 211 of the first peripheral portion, for details, it can refer to the descriptions of the specific positional relationship between the first portion 221 of the second peripheral portion and the first portion 211 of the first peripheral portion, in this way, a similar light blocking effect and a technical effect of preventing the problem of light crosstalk between the adjacent sub-pixels can be achieved in the non-display region where the third sub-layer 222a and the fourth sub-layer 222b are stacked with the first portion 231 of the third peripheral portion.

For example, the third color filter 23 is a red color filter that allows red light to pass through, that is, in the display panel provided by at least one embodiment, the first color filter 21 is a green color filter that allows green light to pass through, the second color filter 22 is a blue color filter that allows blue light to pass through, and the third color filter 23 is a red color filter that allows red light to pass through. Of course, the color filters are not limited to the colors listed above, as long as the light transmittance of the second color filter 22 is smaller than the light transmittance of the first color filter 21, and is smaller than the light transmittance of the third color filter 23.

For example, the second color filter 22 is substantially axisymmetric with respect to the symmetry axis along the longitudinal direction, thus in various embodiments, the second portion 222 and the first portion 221 of the second peripheral portion of the second color filter 22 may have symmetrical structures with respect to the symmetry axis in the longitudinal direction. For example, the first peripheral portions and the third peripheral portions adjacent to each other are also substantially axisymmetric with respect to the symmetry axis in the longitudinal direction. In this way, a better light blocking effect can be achieved in the non-display regions 04 at both two ends of the second color filter 22 in the lateral direction, and the problem of light crosstalk between the adjacent sub-pixels can be better prevented.

For example, as shown in FIG. 2A to 2B, a cross section of the second color filter 22 in the longitudinal direction is substantially in a shape of a Chinese word “1”, and, a middle region of the second color filter 22 on the surface away from the substrate 1 has a depression, to reduce the thickness of the part of the second color filter 22 in the light-emitting region (that is, the opening region) in the longitudinal direction, that is, the thickness of the second light-transmitting portion 220 in the longitudinal direction is reduced, so that the problem that the thickness of the second light-transmitting portion 220 is increased which problem is caused by the second color filter 22 having a plurality of stacked sub-layers is avoided, and thus it is avoided that the thickness of the second light-transmitting part 220 is large, which affects the light transmittance. For example, in the display panel provided by the embodiment of the present disclosure, with reference to FIG. 1, one first color filter 21, one second color filter 22 and one third color filter 23 that are arranged in sequence constitute a repeating unit, and a plurality of repeating units are repeatedly arranged to provide one color filter for each of the plurality of sub-pixels 01/02/03.

For example, as shown in FIG. 2A to FIG. 2B, in one repeating unit, the first peripheral portion of the first color filter 21 further includes a second portion 212 located on a side of the first transparent portion 210 away from the second color filter 22, and the third peripheral portion further includes a second portion 232 located on a side of the third light-transmitting portion close to the first color filter 21 of the adjacent repeating unit. The second portion 212 of the first peripheral portion comprises a plurality of sub-layers that are at least partially overlapped in the longitudinal direction perpendicular to the main surface 1a of the substrate 1 and are spaced apart from each other in the longitudinal direction, for example, the plurality of sub-layers of the first peripheral portion include a fifth sub-layer 212a and a sixth sub-layer 212b, at least a part of the second portion 232 of the third peripheral portion of the third color filter 23 in the repeating unit adjacent to the one repeating unit is located between the fifth sub-layer 212a and the sixth sub-layer 212b in the longitudinal direction. Therefore, a better light blocking effect is achieved in the non light-emitting region 04 where the second portion 212 of the first peripheral portion and the second portion 232 of the third peripheral portion are overlapped, and the problem of light crosstalk between adjacent sub-pixels can be better prevented.

For example, in one repeating unit, the shape and the size of the second portion 212 of the first peripheral portion are respectively substantially the same as the shape and the size of the first portion 221 of the second peripheral portion; the shape and the size of the second portion 232 of the third peripheral portion are respectively substantially the same as the shape and the size of the first portion 211 of the first peripheral portion, so that the same or similar technical effects as the above-mentioned features related to the first portion 221 of the second peripheral portion and the features related to the first portion 211 of the first peripheral portion are achieved, therefore, the related features of the shape and the size of the second portion 212 of the first peripheral portion, and the related features of the shape and the size of the second portion 232 of the third peripheral portion are not repeated herein, which can refer to the previous descriptions of the features related to the first portion 221 of the second peripheral portion and the features related to the first portion 211 of the first peripheral portion.

For example, as shown in FIG. 2A to FIG. 2B, in an upper surface of the first color filter 21 away from the substrate 1, a position where the second portion 212 of the first peripheral portion borders the first light-transmitting portion 210 has a stepped structure to reduce the thickness of the first light-transmitting portion 210 in the longitudinal direction, so that the problem that the thickness of the first light-transmitting portion 210 is increased which problem is caused by the first color filter 21 having a plurality of stacked sub-layers is avoided, and thus it is avoided that the thickness of the first light-transmitting portion 210 is large, which affects the light transmittance.

For example, as shown in FIG. 2A to FIG. 2B, a cross-sectional shape of the third color filter 23 in the longitudinal direction is in a shape of a Chinese word and the protrusion of the shape of the Chinese word “i” protrudes toward the substrate.

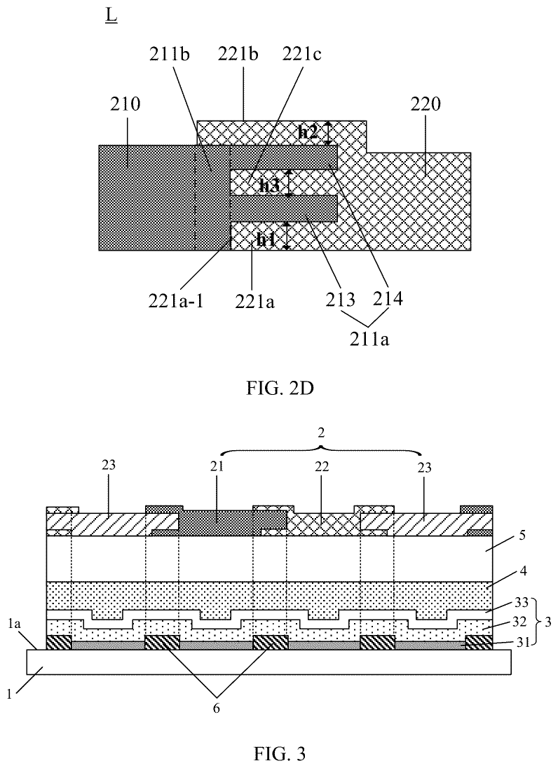

For example, in at least one embodiment shown in FIG. 3, the display panel 10 further includes a pixel definition layer 6, the pixel definition layer 6 defines openings for the plurality of sub-pixels of the pixel array, the light-emitting devices are at least partially located in the openings; orthographic projections of the first light-transmitting portion 210, the second light-transmitting portion 220 and the third light-transmitting portion 230 on the main surface 1a of the substrate 1 are respectively located in orthographic projections of the openings of the sub-pixels corresponding to the first color filter 21, the second color filter 22 and the third color filter 23 on the main surface 1a of the substrate 1, and orthographic projections of the first peripheral portion, the second peripheral portion and the third peripheral portion on the main surface 1a of the substrate 1 are all located within an orthographic projection of the pixel definition layer 6 on the main surface 1a of the substrate 1, to maximize the aperture ratio of the display panel 10. In this case, for example, the substrate 1 is a glass substrate, a quartz substrate, or a flexible substrate, and display apparatus such as pixel circuits are manufactured on the substrate 1 by using a semiconductor process.

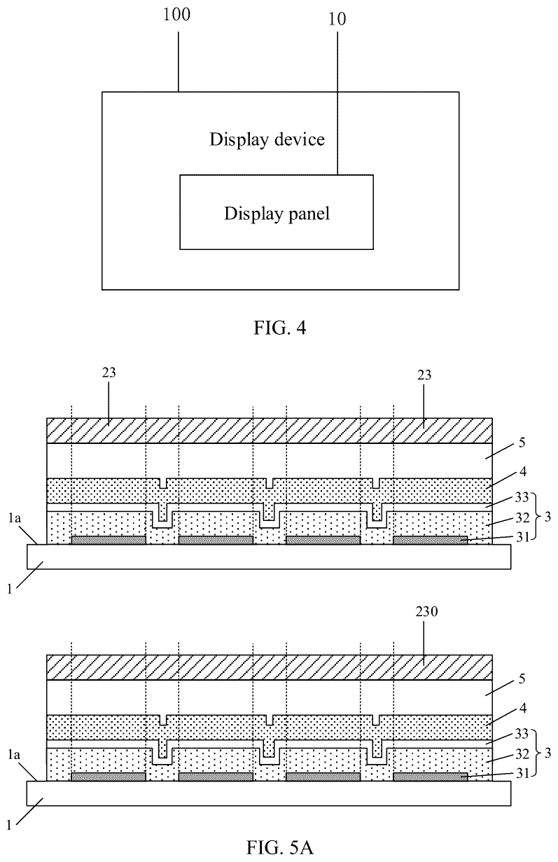

For example, at least one embodiment of the present disclosure further provides a display apparatus 100, as shown in FIG. 4, the display apparatus includes any one of the display panels 10 provided in the embodiments of the present disclosure.

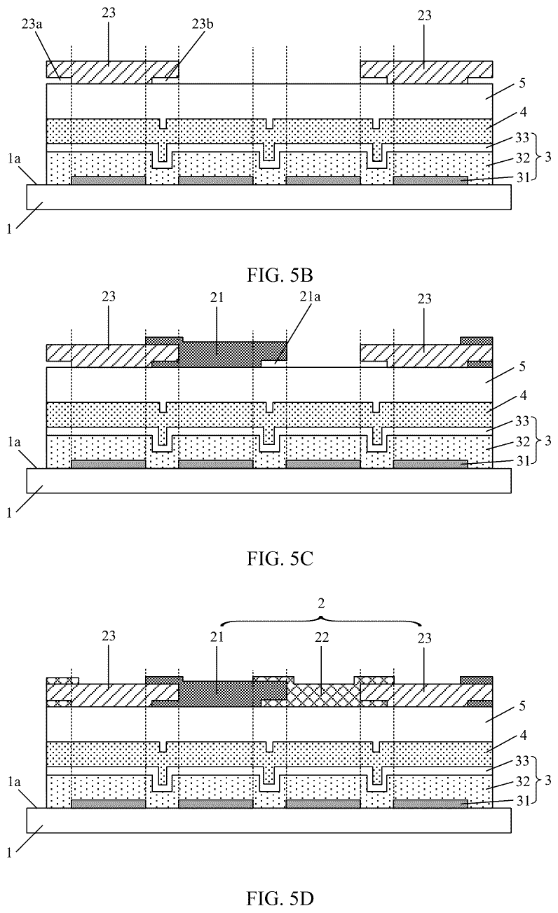

FIG. 5A to FIG. 5D are schematic diagrams of a manufacturing method of a display panel provided by at least one embodiment of the present disclosure, for example, are schematic diagrams of the manufacturing method of the display panel shown in FIG. 1A. For example, in at least one embodiment, the display panel may be manufactured in an order of FIG. 5A to FIG. 5D.

As shown in FIG. 5A, a substrate 1 is provided, for example, the substrate 1 is a silicon-based substrate; the display panel 10 is encapsulated to form the above-mentioned thin film encapsulation layer 4; and a flat layer 5 is formed on the thin film encapsulation layer 4; and a third color filter material layer 23 is formed on the flat layer 5.

As shown in FIG. 5B, a patterning process is performed on a third color filter material layer 23 to form the third color filter 23, and a first notch 23a and a second notch 23b are respectively formed on a side of two ends of the third color filter 23 close to the substrate 1; the specific structural features of the third color filter 23 may be referred to the descriptions of the embodiment shown in FIG. 1A.

For example, the patterning process is an exposure-development process. An exposure machine may be used to determine the positions where the first notch 23a and the second notch 23b are located as focus positions, the exposure value is arranged to a suitable negative value, the first notch 23a and the second notch 23b can be formed after performing the developing process on the exposed third color filter material layer 23, and the third color filter 23 as shown in 5B is obtained. Specifically, those skilled in the art can use conventional techniques in the art to achieve the third color filter 23.

As shown in FIG. 5C, a first color filter material is coated to form a first color filter material layer, the first color filter material is filled in the first notch 23a but not filled in the second notch 23b, for example, a spin coating method may be used to fill the first color filter material into the first notch 23a, similarly, an exposure method similar to that performed on the third color filter material layer 23 is performed on the first color filter material layer, the first color filter 21 shown in FIG. 5C can be formed after developing, and a side of the first color filter close to the substrate 1 away from the end of the third color filter 23 in contact with the first color filter has a third notch 21a.

As shown in FIG. 5D, a second color filter material is coated to form a second color filter material layer, and the second color filter material is filled in the second notch 23b and the third notch 21a; for example, the second color filter material layer covers the plurality of sub-pixels in the display region, for example, covers the first color filter 22 and the third color filter 23, and a patterning process is performed on the second color filter material layer to obtain the second color filter 22 shown in FIG. 5D. For the specific structural features of the second color filter 22 corresponding to one of the sub-pixels, it can refer to the descriptions in the previous embodiments, which are not repeated herein.

What are described above is related to only the illustrative embodiments of the present disclosure and not limitative to the protection scope of the present application. Therefore, the protection scope of the present application shall be defined by the accompanying claims.

1. A display panel, comprising:
a substrate, comprising a main surface;
a plurality of sub-pixels, arranged in an array on the main surface of the substrate, wherein each of the plurality of sub-pixels comprises a light-emitting device and a color filter on a light-emitting side of the light-emitting device; the color filter of the plurality of sub-pixels comprises a first color filter and a second color filter that are adjacent, light transmission color of the first color filter and light transmission color of the second color filter are different from each other, and light transmittance of the second color filter is smaller than light transmittance of the first color filter;
the first color filter comprises a first light-transmitting portion and a first peripheral portion, the first light-transmitting portion is configured to allow light of the sub-pixel where the first light-transmitting portion is located to pass through to emit from the display panel; the first peripheral portion at least partially surrounds the first light-transmitting portion, and comprises a first portion located on a side of the first light-transmitting portion close to the second color filter;
the second color filter comprises a second light-transmitting portion and a second peripheral portion, the second light-transmitting portion is configured to allow light of the sub-pixel where the second light-transmitting portion is located to pass through to emit from the display panel; the second peripheral portion at least partially surrounds the second light-transmitting portion, and comprises a first portion located on a side of the second light-transmitting portion close to the first color filter;
the first portion of the second peripheral portion comprises a plurality of sub-layers that are at least partially overlapped and spaced apart from each other in a longitudinal direction perpendicular to the main surface of the substrate, the plurality of sub-layers comprise a first sub-layer and a second sub-layer, and at least a part of the first portion of the first peripheral portion is located between the first sub-layer and the second sub-layer in the longitudinal direction.

2. The display panel according to claim 1, wherein the second color filter is a blue color filter that allows blue light to pass through.

3. The display panel according to claim 1, wherein the first sub-layer is on a side of the second sub-layer close to the substrate;
an orthographic projection of the first sub-layer on the main surface of the substrate is within an orthographic projection of the second sub-layer on the main surface of the substrate, and an area of the orthographic projection of the first sub-layer on the main surface of the substrate is smaller than an area of the orthographic projection of the second sub-layer on the main surface of the substrate.

4. The display panel according to claim 3, wherein a direction in which the first color filter and the second color filter are arranged is a lateral direction; and
a width of the first sub-layer in the lateral direction is smaller than a width of the second sub-layer in the lateral direction.

5. The display panel according to claim 4, wherein the first portion of the first peripheral portion comprises:
an inner portion, sandwiched between the first sub-layer and the second sub-layer, wherein the inner portion is overlapped with both the first sub-layer and the second sub-layer in the longitudinal direction;
an outer portion, integral with the inner portion and on a side of the inner portion close to the first light-transmitting portion in the lateral direction, wherein the outer portion is not overlapped with the first sub-layer, and is overlapped with the second sub-layer in the longitudinal direction.

6. The display panel according to claim 5, wherein the outer portion covers a side surface of the first sub-layer and is in contact with the side surface of the first sub-layer, and the side surface of the first sub-layer is intersected with the lateral direction.

7. The display panel according to claim 1, wherein the first sub-layer is on a side of the second sub-layer close to the substrate; and
a thickness of the first sub-layer in the longitudinal direction is greater than a thickness of the second sub-layer in the longitudinal direction.

8. The display panel according to claim 1, wherein the first portion of the first peripheral portion comprises a plurality of sub-layers that are at least partially overlapped in the longitudinal direction and are spaced apart from each other in the longitudinal direction; and
the plurality of sub-layers of the first portion of the first peripheral portion and the plurality of sub-layers of the first portion of the second peripheral portion are alternately stacked in the longitudinal direction.

9. The display panel according to claim 8, wherein among the plurality of sub-layers of the first portion of the first peripheral portion and the plurality of sub-layers of the first portion of the second peripheral portion, the first sub-layer is closest to the substrate.

10. The display panel according to claim 9, further comprising:
a flat layer, covering the main surface of the substrate, and having a flat surface away from the substrate, wherein the first color filter and the second color filter are located on the flat surface, and the first sub-layer is in contact with the flat surface.

11. The display panel according to claim 8, wherein among the plurality of sub-layers of the first portion of the first peripheral portion and the plurality of sub-layers of the first portion of the second peripheral portion, the second sub-layer is farthest away from the substrate.

12. The display panel according to claim 8, wherein the plurality of sub-layers of the first portion of the second peripheral portion are arranged in the longitudinal direction, and in a direction from close to the substrate to away from the substrate, thicknesses of the plurality of sub-layers in the longitudinal direction of the first portion of the second peripheral portion gradually decrease.

13. The display panel according to claim 8, wherein a direction in which the first color filter and the second color filter are arranged is a lateral direction;
the plurality of sub-layers of the first portion of the second peripheral portion are arranged in the longitudinal direction, in a direction from close to the substrate to away from the substrate, widths of the plurality of sub-layers of the first portion of the second peripheral portion in the lateral direction gradually increase.

14. The display panel according to claim 1, wherein the color filter of the plurality of sub-pixels further comprises a third color filter adjacent to the second color filter and on a side of the second color filter away from the first color filter, light transmission colors of the first color filter, the second color filter and the third color filter are different from each other, the light transmittance of the second color filter is smaller than a light transmittance of the third color filter;
the third color filter comprises a third light-transmitting portion and a third peripheral portion, the third light-transmitting portion is configured to allow light of the sub-pixel where the third light-transmitting portion is located to pass through to emit from the display panel; the third peripheral portion at least partially surrounds the third light-transmitting portion, and the third peripheral portion comprises a first portion on a side of the third light-transmitting portion close to the second color filter;
the second peripheral portion further comprises a second portion on a side of the second light-transmitting portion close to the third color filter;
the second portion of the second peripheral portion comprises a plurality of sub-layers that are at least partially overlapped in the longitudinal direction perpendicular to the main surface of the substrate and are spaced apart from each other in the longitudinal direction, the plurality of sub-layers of the second portion of the second peripheral portion comprises a third sub-layer and a fourth sub-layer, and at least a part of the first portion of the third peripheral portion is between the third sub-layer and the fourth sub-layer in the longitudinal direction.

15. The display panel according to claim 14, wherein the first color filter is a green color filter that allows green light to pass through, and the third color filter is a red color filter that allows red light to pass through.

16. The display panel according to claim 14, wherein the second color filter is substantially axisymmetric with respect to a symmetry axis along the longitudinal direction, and the first peripheral portion and the third peripheral portion are substantially axisymmetric with respect to the symmetry axis; and
a cross section of the second color filter in the longitudinal direction is substantially in a shape of a Chinese word “ [symbol] ”.

17. (canceled)

18. The display panel according to claim 14, wherein one of the first color filter, one of the second color filter, and one of the third color filter which are sequentially arranged in sequence constitute a repeating unit, and a plurality of the repeating units are repeatedly arranged to provide one of the color filter for each of the plurality of sub-pixels;
in one of the repeating units, the first peripheral portion further comprises a second portion on a side of the first light-transmitting portion away from the second color filter, and the third peripheral portion further comprises a second portion on a side of the third light-transmitting portion close to the first color filter of an adjacent repeating unit; and
the second portion of the first peripheral portion comprises a plurality of sub-layers that are at least partially overlapped in the longitudinal direction perpendicular to the main surface of the substrate and are spaced apart from each other in the longitudinal direction, the plurality of sub-layers of the second portion of the first peripheral portion comprise a fifth sub-layer and a sixth sub-layer, and at least a part of a second portion of the third peripheral portion of the third color filter in the repeating unit adjacent to the one of the repeating units is located between the fifth sub-layer and the sixth sub-layer in the longitudinal direction.

19. (canceled)

20. The display panel according to claim 18, wherein in one of the repeating units, a shape and a size of the second portion of the first peripheral portion are same as a shape and a size of the first portion of the second peripheral portion, respectively;
a shape and a size of the second portion of the third peripheral portion are respectively same as a shape and a size of the first portion of the first peripheral portion; and
a cross section of the third color filter in the longitudinal direction is in a shape of a Chinese word “ [symbol] ”, and a protrusion of the shape of the Chinese word “ [symbol] ” protrudes toward the substrate.

21. (canceled)

22. The display panel according to claim 13, further comprising:
a pixel definition layer, defining openings of the plurality of the sub-pixels of the pixel array, wherein the light-emitting device are at least partially located in the openings;
an orthographic projection of the first light-transmitting portion, an orthographic projection of the second light-transmitting portion, and an orthographic projection of the third light-transmitting portion on the main surface of the substrate are respectively located in orthographic projections of the openings of the sub-pixels corresponding to the first color filter, the second color filter, and the third color filter on the main surface of the substrate respectively, and an orthographic projection of the first peripheral portion, an orthographic projection of the second peripheral portion, and an orthographic projection of the third peripheral portion on the main surface of the substrate are all within an orthographic projection of the pixel definition layer on the main surface of the substrate.

23. A display apparatus, comprising the display panel according to claim 1.
